(19) United States
(12) Patent Application Publication
(10) Pub. No.: US 2022/0108888 A1
(43) Pub. Date: Apr. 7, 2022

(54) Selective Deposition of Germanium

(71) Applicant: Applied Materials, Inc., Santa Clara, CA (US)

(72) Inventors: Huiyuan Wang, Santa Clara, CA (US); Susmit Singha Roy, Sunnyvale, CA (US); Abhijit Basu Mallick, Palo Alto, CA (US)

(73) Assignee: Applied Materials, Inc., Santa Clara, CA (US)

(21) Appl. No.: 17/062,630

(22) Filed: Oct. 4, 2020

(51) Int. Cl. H01L 21/02; C23C 16/06; C23C 16/24; C23C 16/30; C23C 16/32; C23C 16/40; C23C 16/02

(52) U.S. Cl. CPC H01L 21/02636; H01L 21/02532; H01L 21/02381; H01L 21/02661; C23C 16/0227; C23C 16/24; C23C 16/308; C23C 16/325; C23C 16/401; C23C 16/06

(57) ABSTRACT

Methods for selectively depositing germanium containing films are disclosed. Some embodiments of the disclosure provide deposition on a bare silicon with little to no deposition on a silicon oxide surface. Some embodiments of the disclosure provide conformal films on trench sidewalls. Some embodiments of the disclosure provide superior gap fill without seams or voids.

### TECHNICAL FIELD

Embodiments of the disclosure relate to methods for selectively depositing films comprising germanium. More particularly, embodiments of the disclosure are directed to methods of selectively depositing germanium within substrate features.

### BACKGROUND

The semiconductor industry faces many challenges in the pursuit of device miniaturization which involves rapid scaling of nanoscale features. Such issues include the introduction of complex device fabrication processes with multiple lithography steps and etch. Furthermore, the semiconductor industry would like low cost alternatives to high cost EUV for patterning complex architectures. To maintain the cadence of device miniaturization and keep chip manufacturing costs down, selective deposition has shown promise as it has the potential to remove costly lithographic steps by simplifying integration schemes.

Selective deposition of materials can be accomplished in a variety of ways. For instance, some process may have inherent selectivity to surfaces based on their surface chemistry. For example some methods are known to selectively deposit on silicon or metal surfaces over dielectrics (e.g., silicon oxides).

Further, germanium is a versatile material in the formation of semiconductor manufacturing. Silicon-germanium alloys are rapidly becoming an important semiconductor material for high-speed integrated circuits. Circuits utilizing the properties of Si—SiGe junctions can be much faster than those using silicon alone. Silicon-germanium is also beginning to replace gallium arsenide (GaAs) in many wireless communications devices. Germanium-on-insulator (GeOI) substrates are also seen as a potential replacement for silicon on miniaturized chips. Other uses in electronics include phosphors in fluorescent lamps and solid-state light-emitting diodes (LEDs).

Accordingly, there is a need for methods of selectively depositing germanium containing films to further utilize these materials in ever shrinking electronic devices.

### SUMMARY

One or more embodiments of the disclosure are directed to a method of selective deposition. The method comprises exposing a substrate to a reactive gas comprising a germanium precursor to selectively deposit a germanium containing film on a second material comprising silicon and/or germanium with substantially no oxygen over a first material comprising silicon and oxygen. The substrate comprises a plurality of features with each feature having a depth from a top to a bottom and a width between two sidewalls. The bottom comprises the first material and the sidewalls comprise the second material.

Additional embodiments of the disclosure are directed to a method of selective deposition. The method comprises exposing a substrate maintained at a temperature in a range of 500° C. to 800° C. to a reactive gas comprising germane and hydrogen gas to selectively deposit a conformal germanium containing film on a second material consisting essentially of silicon over a first material comprising silicon and oxygen. The substrate comprises a plurality of features with each feature consisting of a bottom and two sidewalls, The bottom comprises the first material and the sidewalls comprise the second material.

Further embodiments of the disclosure are directed to a method of bottom up gap fill. The method comprises exposing a substrate to a reactive gas comprising a germanium precursor to selectively deposit a germanium containing film on a second material comprising silicon and/or germanium with substantially no oxygen over a first material comprising silicon and oxygen. The substrate comprises a plurality of features with each feature having a depth from a top to a bottom and a width between two sidewalls. The bottom comprises the second material and the sidewalls comprise the first material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a side view of an exemplary substrate before processing according to one or more embodiment of the disclosure;

FIG. 1B is a top view of an exemplary substrate before processing according to one or more embodiment of the disclosure;

FIG. 2 is a cross-sectional side view of an exemplary substrate during processing according to one or more embodiment of the disclosure;

FIG. 3A is a side view of an exemplary substrate before processing according to one or more embodiment of the disclosure;

FIG. 3B is a top view of an exemplary substrate before processing according to one or more embodiment of the disclosure; and

FIG. 4 is a cross-sectional side view of an exemplary substrate during processing according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

One or more embodiments of the disclosure are directed to methods for selectively depositing germanium containing films. In some embodiments, the methods advantageously provide methods for selectively depositing germanium or a silicon germanium alloy. In some embodiments, the methods advantageously provide conformal germanium containing films. In some embodiments, the methods advantageously provide for the deposition of germanium containing films on silicon over silicon oxides.

As used in this specification and the appended claims, the term “selectively depositing a film on a first surface over a second surface”, and the like, means that a first amount of the film is deposited on the first surface and a second amount of film is deposited on the second surface, where the first amount of film is greater than the second amount of film, or no film is deposited on the second surface.

The term “over” used in this regard does not imply a physical orientation of one surface on top of another surface, rather a relationship of the thermodynamic or kinetic properties of the chemical reaction with one surface relative to the other surface. For example, selectively depositing a cobalt film onto a metal surface over a dielectric surface means that the cobalt film deposits on the metal surface and less or no cobalt film deposits on the dielectric surface; or that the formation of a cobalt film on the metal surface is thermodynamically or kinetically favorable relative to the formation of a cobalt film on the dielectric surface.

The selectivity of a deposition process is generally expressed as a multiple of growth rate. For example, if one surface is deposited on 25 times faster than a different surface, the process would be described as having a selectivity of 25:1 or simply 25. In this regard, higher ratios indicate more selective processes.

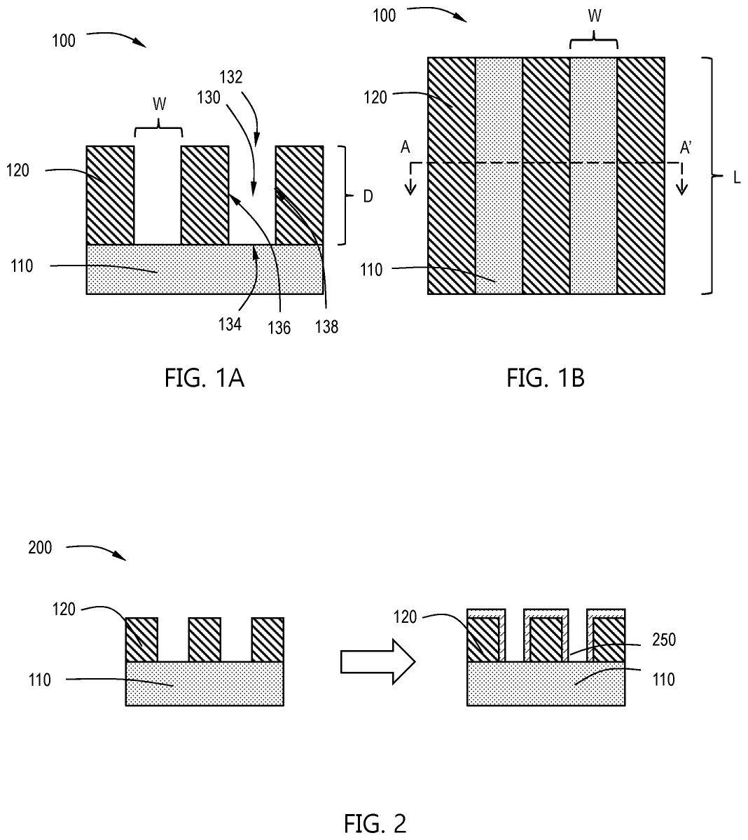

Referring to FIGS. 1A, 1B and 2, an exemplary method 200 beings with a substrate 100. For clarity, FIG. 1B illustrates a top view of a substrate 100. FIG. 1A illustrates a cross-sectional side view along A-A′ as shown in FIG. 1B. The substrate 100 comprises a first material 110 and a second material 120.

The substrate 100 comprises a plurality of features 130. Each feature 130 has a depth D from the top 132 of the feature 130 to a bottom 134 of the feature 130 and a width W between two sidewalls 136, 138. The material at the bottom 134 comprises the first material 110 and the sidewalls 136, 138 comprise the second material 120.

In some embodiments, as shown in FIG. 1B, each feature 130 is a trench with a length L greater than the width W. In some embodiments, the ratio between length L and width W is greater than or equal to 2, greater than or equal to 5, greater than or equal to 10, greater than or equal to 20, greater than or equal to 50, greater than or equal to 100, or greater than or equal to 500. In some embodiments not shown in FIG. 1B, the length L of the feature 130 is bounded by vertical walls. In some embodiments, the length L of the feature 130 is bounded only by the edge of the substrate 100.

In some embodiments, the width W of the feature 130 is in a range of 10 nm to 100 nm, a range of 20 nm to 50 nm, in a range of 30 nm to 40 nm, in a range of 10 nm to 50 nm or in a range of 15 nm to 30 nm. In some embodiments, the width W of the feature 130 is about 20 nm. In some embodiments, the depth D of the feature 130 is in a range of 5 nm to 100 nm, 10 nm to 50 nm, or in a range of 15 nm to 30 nm. In some embodiments, the ratio between the depth D and the width W (i.e., aspect ratio) is in a range of 0.1 to 10, in a range of 0.25 to 4, in a range of 0.5 to 2, or in a range of 0.5 to 1. In some embodiments, the depth D is greater than the width W and the aspect ratio is in a range of 1 to 20, in a range of 2 to 20, in a range of 5 to 20 or in a range of 10 to 20.

The first material 110 comprises silicon and oxygen. In some embodiments, the first material comprises one or more of SiO, SiOC, SiON or SiOCN. In some embodiments, the first material 110 consists essentially of silicon oxide. In some embodiments, the first material consists essentially of silicon dioxide (SiO₂).

Unless stated otherwise, the material compositions identified within this disclosure and the appended claims do not assume any specific ratio of the identified elements. For example, SiO or silicon oxide should be understood as any material comprising silicon and oxygen without assuming any specific ratio there between. In contrast, SiO₂ should be understood as a material comprising silicon and oxygen with an atomic ratio of 1:2, respectively. As used herein, a material which “consists essentially of” an identified material comprises greater than 95%, greater than 98%, greater than 99% or greater than 99.5% of the stated material on an atomic basis.

The second material 120 comprises silicon and/or germanium with substantially no oxygen. As used in this regard, a material with “substantially no oxygen” has less than 2%, less than 1% or less than 0.5% oxygen on an atomic basis. In some embodiments, the second material 120 consists essentially of Si, Ge or SiGe.

Referring to FIG. 2, the method 200 comprises exposing the substrate 100 to a reactive gas comprising a germanium precursor to selectively deposit a germanium containing film 250 on the second material 120 over the first material 110.

In some embodiments, the germanium precursor comprises or consists essentially of germane (GeH₄). In some embodiments, the germanium precursor comprises one or more of germane, digermane, isobutylgermane, chlorogermane or dichlorogermane.

In some embodiments, the reactive gas further comprises hydrogen gas (H₂). In some embodiments, the hydrogen gas is used as a carrier or diluent for the germanium precursor. In some embodiments, the reactive gas comprises or consists essentially of germane and hydrogen gas. In some embodiments, the molar percentage of germane in the reactive gas is in a range of 1% to 50%, in a range of 2% to 30% or in a range of 5% to 20%.

In some embodiments, the germanium containing film 250 comprises an atomic percentage of germanium greater than or equal to 50%. In this regard, the germanium containing film 250 may be described as a “germanium-rich film”. In some embodiments, the atomic percentage of germanium in the germanium containing film 250 is greater than or equal to 60%, greater than or equal to 70%, greater than or equal to 80% greater than or equal to 90%, greater than or equal to 95%, greater than or equal to 98%, greater than or equal to 99% or greater than or equal to 99.5%. Stated differently, in some embodiments, the germanium containing film 250 consists essentially of germanium.

In some embodiments, the germanium containing film 250 comprises silicon and germanium. Stated differently, in some embodiments, the germanium containing film 250 comprises SiGe.

In some embodiments, when the germanium containing film 250 comprises silicon, the reactive gas further comprises a silicon containing precursor. In some embodiments, the silicon containing precursor comprises one or more of silane (SiH₄), a polysilane, or a halosilane. As used in this regard, a “polysilane” is a species with the general formula SiₙH₂ₙ₊₂ where n is 2 to 6. Further, a “halosilane” is a species with the general formula SiₐX_{b}H_{2a+2-b} where X is a halogen, a is 1-6, and b is 1 to 2a+2. In some embodiments, the silicon containing precursor comprises one or more of SiH₄, Si₂H₆. Si₃H₈, Si₄H₁₀, SiCl₄, or SiH₂Cl₂.

In some embodiments, the germanium containing film 250 is selectively deposited on the second material over the first material. In some embodiments, the selectivity is greater than or equal to 5, greater than or equal to 10, greater than or equal to 20, greater than or equal to 30, or greater than or equal to 50. In some embodiments, the germanium containing film 250 may be deposited on the second material 120 to a thickness before deposition is observed on the first material 110. In some embodiments, greater than 50 nm, greater than 100 nm, greater than 150 nm, greater than 200 nm or greater than 250 nm of the germanium containing film 250 is deposited on the second material 120 before 5 nm of film is deposited on the first material 110.

The temperature of the substrate 100 may be maintained during processing In some embodiments, the substrate 100 is maintained at a temperature in a range of 300° C. to 800° C., in a range of 400° C. to 800° C., in a range of 500° C. to 800° C., in a range of 250° C. to 600° C., in a range of 400° C. to 600° C., or in a range of 500° C. to 600° C. In some embodiments, the substrate is maintained at about 540° C.

The pressure of the processing chamber may be maintained during processing. In some embodiments, the pressure is maintained in a range of 1 Torr to 300 Torr, in a range of 10 Torr to 300 Torr, in a range of 50 Torr to 300 Torr, in a range of 100 Torr to 300 Torr, in a range of 200 Torr to 300 Torr or in a range of 1 Torr to 20 Torr. In some embodiments, the pressure is maintained at about 13 Torr.

In some embodiments, the substrate 100 is pre-treated before exposure to the reactive gas. In some embodiments, a native oxide layer is removed from the second material 120 before exposing the substrate 100 to the reactive gas. In some embodiments, the native oxide is removed by exposing the substrate 100 to a plasma formed from a plasma gas. In some embodiments, the plasma gas comprises or consists essentially of hydrogen gas (H₂). In some embodiments, the plasma gas comprises ammonia (NH₃) or nitrogen gas (N₂). In some embodiments, the plasma gas consists essentially of nitrogen gas (N₂) and hydrogen gas (H₂). In some embodiments, the plasma gas consists essentially of ammonia (NH₃) and hydrogen gas (H₂).

In some embodiments, the ratio between nitrogen gas or ammonia and hydrogen gas may be controlled. In some embodiments, the ratio (N/H) is in a range of 5 to 0.5 or in a range of 2 to 1

In some embodiments, the germanium containing film 250 is substantially conformal over the second material 120 of the substrate 100. As used in this regard, a film is “substantially conformal” if the thickness of the film at every point is within 20%, within 10% or within 10% to 20% of the average thickness of the film.

In some embodiments, the germanium containing film 250 has a low roughness. In some embodiments, the surface roughness of the germanium containing film 250 is less than or equal to 1 nm (Rms).

Without being bound by theory, it is believed that films deposited within features are typically of lower quality than blanket films. However, the differences in film quality are not readily noticeable or problematic when the feature is a small via. Yet when the feature is expanded to a trench, poor film quality may be more apparent. Accordingly, the inventors found the film quality of the germanium containing film deposited within the trench by the disclosed method to be surprisingly superior.

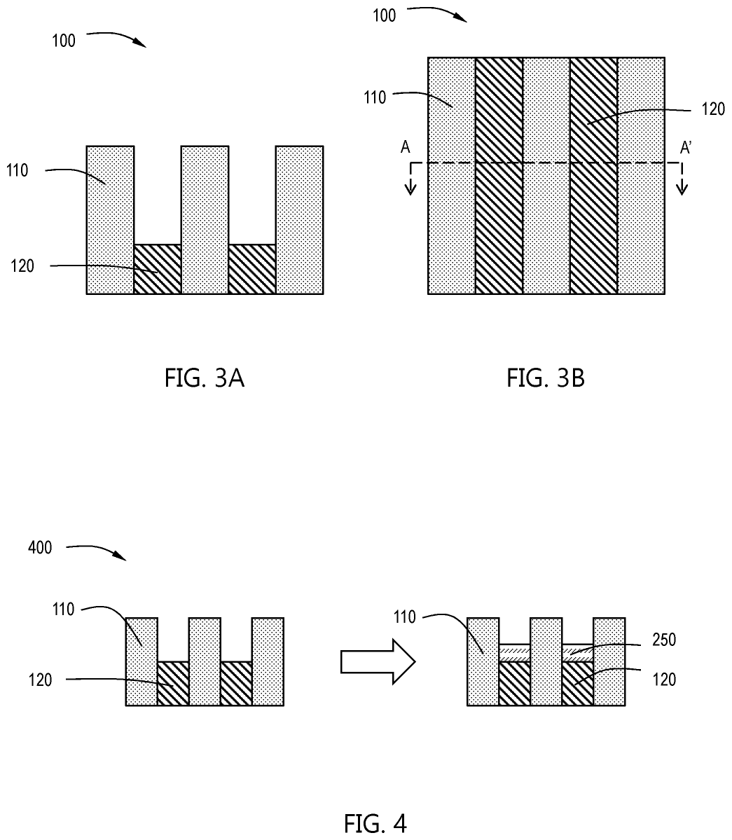

Referring to FIGS. 3A, 3B and 4, a similar method 400 is disclosed in which the first material 110 and the second material 120 are switched in terms of position. The bottom 134 of the feature 130 comprises the second material 120 and the sidewalls 136, 138 comprise the first material.

Referring to FIG. 4, the germanium containing film 250 is selectively deposited on the second material 120 over the first material 110. In this arrangement, the film forms a gap fill within the feature 130 which is deposited from the bottom 134 towards the top 132. This process may be referred to as a bottom-up gap fill process.

Without being bound by theory, it is believe that the bottom-up gap fill process disclosed herein advantageously provides a germanium containing film (gap fill) without the possibility of forming seams, voids or other film irregularities within the feature 130.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of selective deposition, the method comprising exposing a substrate to a reactive gas comprising a germanium precursor to selectively deposit a germanium containing film on a second material comprising silicon and/or germanium with substantially no oxygen over a first material comprising silicon and oxygen, the substrate comprising a plurality of features, each feature having a depth from a top to a bottom and a width between two sidewalls, the bottom comprising the first material and the sidewalls comprising the second material.

2. The method of claim 1, wherein the germanium precursor comprises germane (GeH₄).

3. The method of claim 2, wherein the germanium precursor is diluted with hydrogen gas (H₂).

4. The method of claim 3, wherein a molar percentage of germane in the reactive gas is in a range of 1% to 50%.

5. The method of claim 1, wherein the germanium containing film comprises SiGe.

6. The method of claim 5, wherein the reactive gas further comprises silane, a polysilane or a halosilane.

7. The method of claim 1, wherein the germanium containing film consists essentially of germanium.

8. The method of claim 1, wherein the first material comprises SiO, SiOC, SiON, or combinations thereof.

9. The method of claim 1, wherein the second material consists essentially of Si, Ge, or SiGe.

10. The method of claim 1, wherein the width is in a range of 30 nm to 40 nm.

11. The method of claim 1, wherein the depth is in a range of 15 nm to 30 nm.

12. The method of claim 1, wherein ratio between the depth and the width is in a range of 0.5 to 1.

13. The method of claim 1, further comprising removing a native oxide from the second material of the substrate before exposing the substrate to the reactive gas.

14. The method of claim 13, wherein the native oxide is removed by exposing the substrate to a plasma formed from a plasma gas.

15. The method of claim 14, wherein the plasma gas consists essentially of hydrogen gas (H₂) or hydrogen gas and nitrogen gas (H₂/N₂).

16. The method of claim 1, wherein the substrate is maintained at a temperature in a range of 300° C. to 800° C.

17. The method of claim 1, wherein the germanium containing film is substantially conformal over the second material of the substrate.

18. The method of claim 1, wherein the germanium containing film has a roughness of less than or equal to 1 nm (Rms).

19. A method of selective deposition, the method comprising exposing a substrate maintained at a temperature in a range of 500° C. to 800° C. to a reactive gas comprising germane and hydrogen gas to selectively deposit a conformal germanium containing film on a second material consisting essentially of silicon over a first material comprising silicon and oxygen, the substrate comprising a plurality of features, each feature consisting of a bottom and two sidewalls, the bottom comprising the first material and the sidewalls comprising the second material.

20. A method of bottom up gap fill, the method comprising exposing a substrate to a reactive gas comprising a germanium precursor to selectively deposit a germanium containing film on a second material comprising silicon and/or germanium with substantially no oxygen over a first material comprising silicon and oxygen, the substrate comprising a plurality of features, each feature having a depth from a top to a bottom and a width between two sidewalls, the bottom comprising the second material and the sidewalls comprising the first material.
